(19) United States
(12) Patent Application Publication
(10) Pub. No.: US 2012/0080308 A1
(43) Pub. Date: Apr. 5, 2012

(54) PLUME STEERING

(75) Inventor: Ikuya Kameyama, Fort Collins, CO (US)

(73) Assignee: Veeco Instruments, Inc., Plainview, NY (US)

(21) Appl. No.: 12/898,424

(22) Filed: Oct. 5, 2010

(51) Int. Cl. C23C 14/34

(52) U.S. Cl. 204/192.11; 204/298.04

(57) ABSTRACT

Non-elliptical ion beams and plumes of sputtered material can yield a relatively uniform wear pattern on a destination target and a uniform deposition of sputtered material on a substrate assembly. The non-elliptical ion beams and plumes of sputtered material impinge on rotating destination targets and substrate assemblies. A first example ion beam grid and a second example ion beam grid each have patterns of holes with an offset between corresponding holes. The quantity and direction of offset determines the quantity and direction of steering individual beamlets passing through corresponding holes in the first and second ion beam grids. The beamlet steering as a whole creates a non-elliptical current density distribution within a cross-section of an ion beam and generates a sputtered material plume that deposits a uniform distribution of sputtered material onto a rotating substrate assembly.

### CROSS-REFERENCE TO RELATED APPLICATIONS

The present application is related to U.S. patent application Ser. No. ______ entitled “Ion Beam Distribution” and filed on Oct. 5, 2010; and U.S. patent application Ser. No. ______, entitled “Grid Providing Beamlet Steering” and filed on Oct. 5, 2010, which are specifically incorporated by reference herein for all they disclose or teach.

### BACKGROUND

In an ion beam sputtered deposition system, a beam of ions from an ion source strikes a target with such kinetic energy to sputter atoms off from the target into a plume, which can subsequently deposit these atoms on a substrate assembly. There are a variety of substrate assembly configurations and motions used in conjunction with such an ion beam sputtered deposition system. For example, the substrate assembly may be a single rotating substrate on a substrate assembly. In another implementation, the substrate assembly includes a plurality of individually rotating substrates on a rotating substrate assembly. Further, the sizes and orientation of the substrate assemblies may vary widely. For example, the substrate assembly with the single rotating substrate may have a similar size or a larger size as one of the individually rotating substrates in the substrate assembly with a plurality of individually rotating substrates and either substrate assembly may be arranged at various angles and locations to effect a desired deposition across the substrate assembly.

### SUMMARY

Implementations described and claimed herein provide a substantially circular grid having a pattern of holes for passing beamlets of ions there through, wherein when placed adjacent to another ion beam grid, the beamlets exiting the ion beam grids are steered to form an ion beam that impinges a non-elliptical predetermined area on a destination target. In another implementation, a method of sputtering material from a target comprises steering individual ion beamlets from a substantially circular ion source to form an ion beam that impinges a non-elliptical predetermined area on a destination target.

In yet another implementation, an ion beam system comprises a destination target; a first substantially circular ion beam grid having a first pattern of holes; and a second substantially circular ion beam grid having a second pattern of holes placed adjacent the first ion beam grid, wherein the first pattern of holes are offset from the second pattern of holes in a manner that steers individual ion beamlets to form an ion beam that impinges a non-elliptical predetermined area on the destination target. In still another implementation, a system comprises a pair of substantially circular ion beam grids and a means for steering individual ion beamlets formed in the ion beam grids configured to output an ion beam that impinges a non-elliptical predetermined area on a destination target.

Other implementations are also described and recited herein.

### BRIEF DESCRIPTIONS OF THE DRAWINGS

FIG. 1 illustrates an example block diagram of a beam steering ion beam system.

FIG. 2 illustrates an example implementation of a beam steering ion beam system.

FIG. 3 illustrates an example diagram of a grid assembly used in an ion beam system.

FIG. 4A illustrates an example ideal current density distribution for use with a small substrate assembly.

FIG. 4B illustrates an example ideal current density distribution for use with a large substrate assembly.

FIG. 5A illustrates a first side view of an example ion beam system utilizing a current density distribution for use with a single axis substrate assembly.

FIG. 5B illustrates a second side view of the ion beam system of FIG. 5A at section A-A.

FIG. 5C illustrates an example rotationally integrated deposition flux distribution on the single axis substrate assembly of FIG. 5A.

FIG. 6A illustrates a first side view of an example ion beam system utilizing a current density distribution for use with a multi-axis substrate assembly.

FIG. 6B illustrates a second side view of the ion beam system of FIG. 6A at section B-B.

FIG. 6C illustrates an example rotationally integrated deposition flux distribution on the multi-axis substrate assembly of FIG. 6A.

FIG. 7A illustrates an example single axis substrate assembly for use with an ion beam system incorporating the presently disclosed technology.

FIG. 7B illustrates an example multi-axis substrate assembly for use with an ion beam system incorporating the presently disclosed technology.

FIG. 8 illustrates an example beamlet steering diagram using hole offsets for a steering a single-peak ion beam.

FIG. 9 illustrates an example beamlet steering diagram using grid dishing and hole offsets for steering a single-peak ion beam.

FIG. 10 illustrates an example ion current density profile resulting from the beamlet steering depicted in FIG. 9 impinging on a destination assembly.

FIG. 11 illustrates an example beamlet steering diagram using hole offsets for a steering a double-peak ion beam.

FIG. 12 illustrates an example beamlet steering diagram using grid dishing and hole offsets for steering a double-peak ion beam.

FIG. 13 illustrates an example ion current density profile resulting from the beamlet steering depicted in FIG. 12 impinging on a destination assembly.

FIG. 14 illustrates example operations for creating a non-elliptical plume adapted to impinge on a substrate assembly.

### DETAILED DESCRIPTIONS

During a sputtering operation, an ion beam sputters target material from the target surface, causing areas of the target surface to thin or wear away. However, the sputtering rate from the target surface is typically non-uniform, causing the target to wear away unevenly. When the ion beam sputters away enough target material to reach a certain depth in at least one area on the target, subsequent operation can risk sputtering all the way through the target in that area and reach the base plate and/or an adhesive fixing the target to the base plate. If the ion beam sputters all the way through an area of the target, the adhesive and/or the base plate material may be sputtered to the substrate, thereby contaminating a substrate. Accordingly, a sputtering operation on a particular target is typically terminated before any area of the target is completely worn through, at which point the target is discarded or recycled. As such, the useful lifecycle of a target is limited by the target area experiencing the maximum sputter rate.

The ion beam may also provide a certain shape and distribution of a plume of sputtered material that may not provide for uniform deposition across a particular substrate assembly and/or it may not provide efficient deposition of sputtered material (capture ratio). To address this concern, one or more beam grids may be dished and individually steered to provide an ion beam that either or both better utilizes the target and provides a more advantageous sputter plume shape for uniform, efficient deposition on a particular substrate assembly. The presently disclosed techniques for adapting the ion beam pattern at the target provide a sputtered material plume that matches the overall size and geometric configuration of the corresponding substrate assembly. Further, the presently disclosed techniques for adapting the ion beam pattern at the target also provides a sputtered material plume that matches a specific orientation of one or more substrates on the substrate assembly and/or creates an improved wear pattern on a destination assembly, such as an ion beam sputter target assembly.

In the following description, for the purposes of explanation, numerous specific details are set forth in order to provide a thorough understanding of the present invention. It will be apparent, however, to one skilled in the art that the present invention may be practiced without some of these specific details. For example, while various features are ascribed to particular embodiments, it should be appreciated that the features described with respect to one embodiment may be incorporated with other embodiments as well. By the same token, however, no single feature or features of any described embodiment should be considered essential to the invention, as other embodiments of the invention may omit such features.

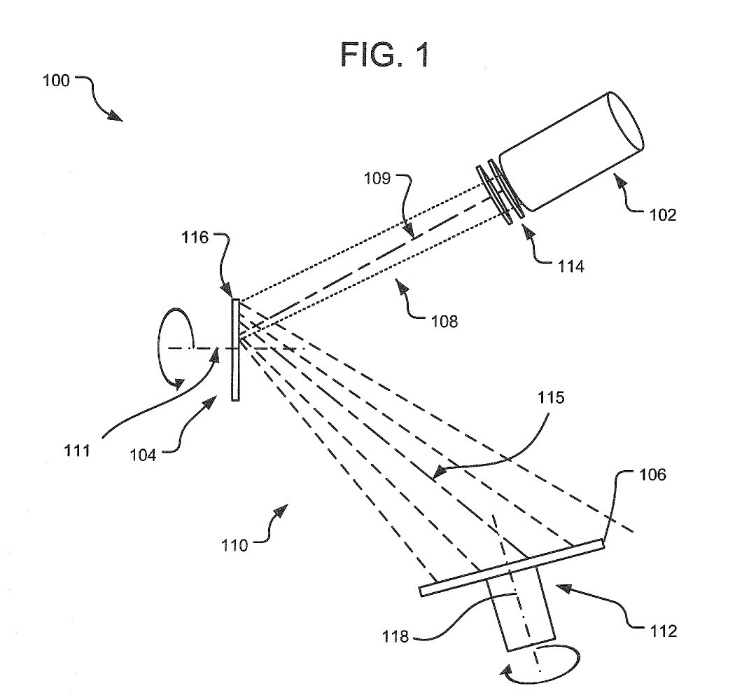

FIG. 1 illustrates an example block diagram of a beam steering ion beam system 100. Even though the implementation of the ion beam system 100 is implemented as an ion beam sputter deposition system, components of the ion beam system 100 may also be used with some alteration for implementing an ion beam etch system, an ion implantation system, an ion beam deposition system, an ion beam assisted deposition system, etc.

In the illustrated implementation, the ion beam system 100 includes an ion source 102, a work-piece sub-assembly 104, and a substrate assembly 106. The ion beam source 102 generates an ion beam 108 that includes a plurality of ion beamlets. The ion source 102 has a centerline axis 109 that is targeted or directed toward work-piece sub-assembly 104 such that the ion beam 108 completely or near completely intersects the plan of work-piece sub-assembly 104. The ion beam 108, upon striking the work-piece sub-assembly 104, generates a sputter plume 110 of material from a target affixed to a work-piece surface 116 of the work-piece sub-assembly 104. The ion beam 108 strikes the work-piece sub-assembly 104 at such an angle so that the sputter plume 110 generated from the work-piece sub-assembly 104 travels towards the substrate assembly 106. In one implementation of the ion beam system, the sputter plume 110 is divergent as it travels towards the substrate assembly 106 and may partially overspray substrate assembly 106. However, in an alternate implementation, the sputter plume 100 may be made more or less concentrated so that its resulting deposition of material is more effectively distributed over a particular area of the substrate 106.

The substrate assembly 106 is located such that the sputter plume 110 strikes the substrate affixed to the substrate assembly 106 at a desired angle as well. Note that the substrate assembly may refer to a single large substrate or a sub-assembly holder that holds multiple smaller individual substrates. In one example implementation of the ion beam system 100, the substrate assembly 106 is attached to a fixture 112 that allows the substrate assembly 106 to be rotated or moved in a desired manner, including rotation of substrate assembly 106 about its axis 118 or pivoting the fixture 112 to tilt the substrate assembly axis 118 to alter its angle with respect to the sputter plume 110.

In an implementation where the substrate assembly includes a substrate that is being treated, such a substrate in the substrate assembly 106 may be a single or arrayed batch of substantially planar work-pieces such as wafers or optical lenses. Alternatively, in such implementation where the substrate is being treated, the substrate in the substrate assembly 106 may be a single or arrayed batch of work-pieces that has additional 3D features, such as cubic (or faceted) optical crystals, curved optical lenses or cutting tool inserts, for example. In addition, such work-pieces may be masked with mechanical templates or patterned etch resist layers (i.e. photo-resist) to help facilitate selected patterning of deposited films or ion treatment over the surface areas of the work-pieces.

In one implementation of the ion beam system 100, the ion source 102 generates ions that are positively charged. However, in an alternate implementation, the ion source 102 may generate ions that are negatively charged. The subsequent disclosure herein assumes that the ions generated by the ion source 102 are positively charged. The ion source 102 may be a DC type, a radio frequency (RF) type or a microwave type gridded ion source. In such an implementation, a steering structure including a plurality of grids 114 is positioned in the path of the ion beam 108. In one implementation of the ion beam system 100, grids 114 are used to direct the ion beam 108 on the work-piece sub-assembly 104 in a desired manner. In one implementation of the ion beam system 100, the plurality of grids 114 steer the ion beamlets such that the ion beam 108 is divergent from the centerline axis 109 of the ion source 102 if no bulk ion beam steering was provided. In an alternate implementation, the plurality of grids 114 steers the ion beamlets such that the ion beam 108 is not divergent from the centerline axis 109. Alternate implementation may also be provided. As discussed below in further detail, in an example implementation, the grids 114 cause the ion beam 108 to have a symmetric or asymmetric cross-sectional profile around a beam axis.

In one implementation, the individual holes in the grids 114 may be positioned to yield the highest density of holes per area to maximize ions extracted from the ion source 102. In another implementation, the grids 114 may have a rectilinearly or elliptically shaped pattern of holes. Individual holes in a rectilinear or elliptical shaped acceleration grid may be positioned to steer beamlets in a circularly asymmetric distribution. Further, holes in a rectilinearly shaped acceleration grid may be positioned relative to corresponding holes in a rectilinearly shaped screen grid, wherein each offset provides for individual steering angles. In other words, a first beamlet may pass through a first hole in the acceleration grid at a first steering angle. A second beamlet may pass through a second hole in the acceleration grid, adjacent to the first hole, at a second steering angle different from the first steering angle. A third beamlet may pass through a third hole in the acceleration grid, adjacent to the second hole, at a third steering angle different from the second steering angle.

The work-piece sub-assembly 104 is located on a platform (not shown in FIG. 1) that rotates the work-piece sub-assembly 104 about a given axis 111 of a work-piece surface 116. In the implementation illustrated in FIG. 1, the work-piece surface 116 is positioned in a manner so that the ion beam 108 strikes the work-piece surface 116 asymmetrically. As further illustrated below, such asymmetric alignment of the work-piece surface 116 together with its rotation around its axis allows more uniform application of the ion beam on the work-piece surface 116. In one implementation of the ion beam system 100, the target affixed to the work-piece surface 116 is made of a single material, and multiple work-piece surfaces 116 with different materials may be placed and interchanged so that a layer of materials can be deposited to create multi-layer coatings on the surface of substrates in the substrate assembly 106. Examples of such material to be deposited on the substrates include without limitation metallic, such as silicon (Si), molybdenum (Mo), tantalum (Ta), etc., oxides such as silicon dioxide (SiO₂), tantalum pentaoxide (Ta₂O₅), titanium dioxide (TiO₂), etc, and other compounds.

In the implementation illustrated in FIG. 1, the sputter plume 110 is directed to the substrate assembly 106 so that a centerline 115 of the sputter plume is off a central axis 118 of the substrate assembly 106. Furthermore, the sputter plume 110 may be directed to the sputter assembly 106 such that in one implementation, at least some sputter material is sprayed in area around and away from the substrate assembly 106, resulting in overspray. Note that in the implementation shown in FIG. 1, the sputter plume oversprays the substrate assembly 106; in an alternate implementation, the sputter plume may impinge on an area confined to the surface of the substrate assembly 106. In one implementation, the sputter assembly 106 is designed so that it may be rotated around a central axis 118. In an implementation of the ion beam system 100, the target surface 116 is tilted as to the centerline 109. In an alternate embodiment, the substrate 106 is tilted as to the centerline 115 of the sputter plume.

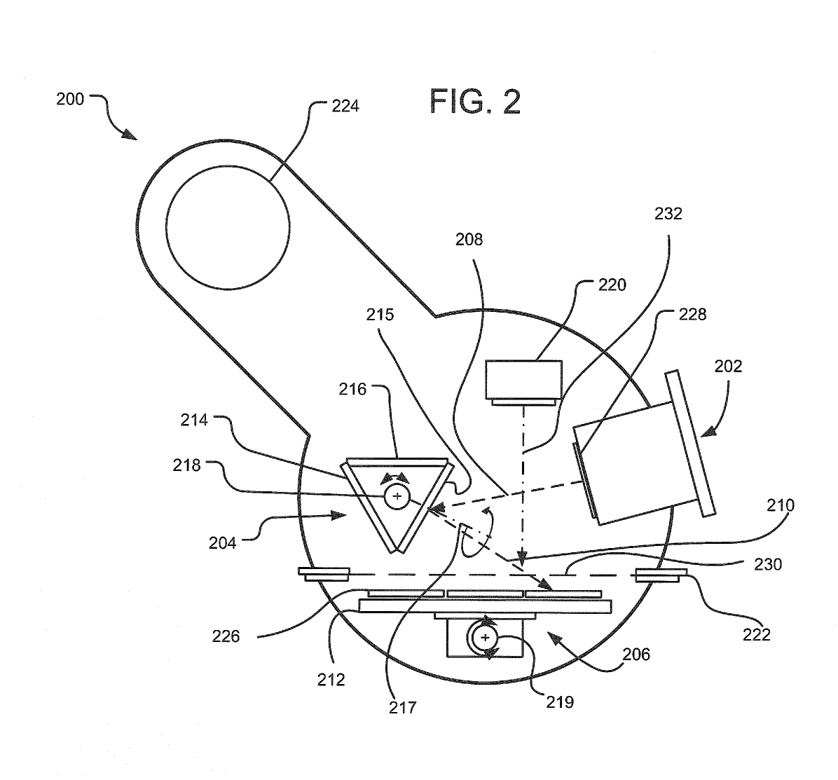

FIG. 2 illustrates an example implementation of a beam steering ion beam system. Specifically, FIG. 2 illustrates a top-down view of a dual ion beam system 200. The ion beam system 200 includes a first RF ion source 202, a target assembly 204, and a substrate assembly 206. The substrate assembly may be tilted around an axis 219. The first RF ion-source 202 generates an ion-beam 208 that is directed towards the target assembly 204. The target assembly 204, upon interaction with the ion-beam 208, generates a sputter plume 210 that is used for deposition on a substrate 226 of the substrate assembly 206. The ion beam system 200 may include a chamber door 222 to effect vacuum conditions in the ion beam system 200. In the illustrated implementation, the chamber door 222 is connected to a door assembly 230 used in maintaining vacuum conditions in the ion beam system 200 as necessary. In one implementation, the substrate 226 is made of a single or arrayed batch of substantially planar work-pieces such as wafers or optical lenses. In an alternate implementation, the substrate 226 is made of a single or arrayed batch of work-pieces that may have additional 3D features, such as cubic (or faceted) optical crystals, curved optical lenses or cutting tool inserts, for example. In addition, such work-pieces may be masked with mechanical templates or patterned etch resist layers (i.e. photo-resist) to help facilitate selected patterning of deposited films or ion treatment over the surface areas of the work-pieces.

The target assembly 204 includes a plurality of target surfaces 214, 215, 216. In one implementation of the ion beam system 100, the target assembly 204 is designed to allow the target surfaces 214, 215, 216 to index around an axis 218 to change from one target 215 to another target 214 or 216. In one implementation of the ion beam system 200, each of the target surfaces 214, 215, 216 have a different material on its surface. Alternatively, the same material may be used on all target surfaces 214, 215, 216. In an alternate implementation, the angle of the active target surface 215 is changed to an alternate static angle relative to the ion beam 208 during deposition. Alternatively, the angle of the active target surface 215 can be oscillated over a range of angles during deposition to help distribute wear across the target surface and to improve deposition uniformity. In an alternate implementation, the work-piece 215 may also be rotated around an axis 217. In an alternate implementation, a second RF ion-source 220 is provided to assist the deposition of the sputter plume 210 on the substrate 226. In one implementation of the ion beam system 100, a gating mechanism (not shown) is used to manage the amount and location of the deposition of the sputter plume 210 on the substrate 226. In one example implementation, the second ion source 220 generates an ion beam 232 that is directed toward the substrate assembly 206. Such an assisting ion beam 232 may be used to either pre-clean or pre-heat the surface of the substrate 226. In an alternate implementation, the assisting ion beam 232 is used in combination with the arrival of material from sputter plume 210 to enhance the surface film deposition kinetics (i.e., material deposition, surface smoothing, oxidation, nitridation, etc.) on substrate 226. In an alternate implementation, the assisting ion beam 232 is used to make deposition of sputter material more dense (or packed) and/or to make the deposition surface smoother.

An implementation of the ion beam system 200 is provided with a vacuum system plenum 224 to generate vacuum condition inside the ion beam system 200. The substrate assembly 206 may be provided with a rotating mechanism to effectively generate a planetary-motion substrate 226. The substrate assembly 206 may also be tilted to alternate angles around an axis 219 either statically or dynamically during deposition in order to improve deposition uniformity across the substrate 226. The first RF ion-source 202 may also include a plurality of grids 228 located in the path of the ion-beam 208 to target or direct the ion-beam in a desired manner.

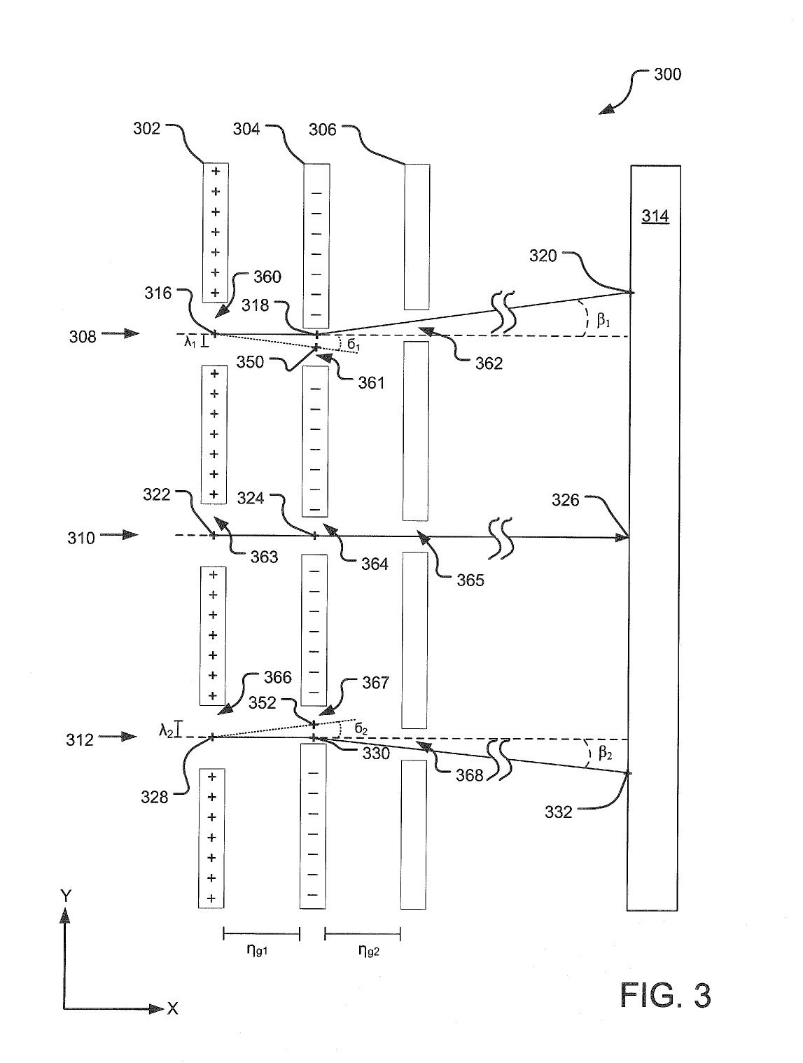

FIG. 3 illustrates an example diagram of a grid assembly 300 used in an ion beam system. The grid assembly 300 comprises a screen grid 302, an acceleration grid 304, and a deceleration grid 306 shown in a cross-sectional view, although it should be understood that different combinations of grids may be employed, including configurations employing a larger number or a fewer number of grids. In one implementation, the grids are circular in shape, with each grid having a substantially similar diameter, although other shapes are contemplated. In another implementation, the grids may have a concave or a convex dished shape.

As shown in FIG. 3, the three grids 302, 304, and 306 are positioned parallel to one another with a distance between each grid measured as η_{g1} and η_{g2}. While the grids are shown positioned parallel to one another, this characteristic is not required. In some implementations, the grids may be slightly non-parallel with slightly varying distances η_{g1} and η_{g2} across the faces of the grids. The grids 302, 304, and 306 are manufactured with an array of corresponding holes. In one implementation, the grids are substantially circular in shape with a substantially circular array of holes, although other grid shapes and hole arrays are contemplated, for example rectangular and elliptical. The grids 302, 304, and 306 are positioned such that the screen grid 302 forms the downstream boundary of a discharge chamber of an ion source (not shown). The discharge chamber generates a plasma of positively charged ions (e.g., from a noble gas, such as argon), and the grids 302, 304, and 306 extract and accelerate ions from the plasma through the grid holes toward a work piece 314 (e.g., a sputter target or substrate). In one implementation, the work piece 314 may be a single or arrayed batch of substantially planar substrates such as wafers or optical lenses or, alternatively, a single or arrayed batch of work pieces that may have additional 3D features, such as cubic (or faceted) optical crystals, curved optical lenses or cutting tool inserts, for example. In addition, such work pieces may be masked with mechanical templates or patterned etch resist layers (i.e. photoresist) to help facilitate selected patterning of deposited films or ion treatment over the surface areas of the work pieces.

Three holes for each grid are shown to illustrate how beamlet steering is achieved for various grid holes that may be applied across the grid assembly system. The work piece 314 may be oriented at an angle relative to the grids 302, 304, and 306. The ions are organized in a collimated ion beam made up of individual beamlets, wherein a beamlet comprises ions accelerating through individual sets of corresponding holes in the grids 302, 304, and 306.

In practice, individual ions of each beamlet flood generally along a center axis through a hole in the screen grid 302 in a distribution across the open area of the hole. The beamlet ions continue to accelerate toward the acceleration grid 304, flooding generally along a center axis through a corresponding hole of the acceleration grid 304. Thereafter, the momentum imparted by the acceleration grid 304 on the beamlet ions propels them generally along a center axis through a hole in the deceleration grid 306 in a distribution across the open area of the hole and toward a downstream positioned work piece 314.

The screen grid 302 is closest to the discharge chamber and is therefore the first grid to receive the emission of ions from the discharge chamber. As such, the screen grid 302 is upstream of the acceleration grid 304 and the deceleration grid 306. The screen grid 302 comprises a plurality of holes strategically formed through the grid. All of the holes in the screen grid 302 may have the same diameter or may have varying diameters across the face of the screen grid 302. Additionally, the distance between the holes may be the same or of varying distances. The screen grid 302 is illustrated in FIG. 3 as four vertical bars in a single column separated by spaces representing three drilled holes 360, 363, and 366 within the screen grid 302. The screen grid 302 is marked with plus (+) signs, representing the screen grid 302 as being positively charged or biased.

The acceleration grid 304 is positioned immediately downstream of the screen grid 302 in FIG. 3, separated by a distance η_{g1}. As such, the acceleration grid 304 is downstream of the discharge chamber and the screen grid 302 and upstream of the deceleration grid 306. The acceleration grid 304 comprises a plurality of holes strategically drilled through the grid, each hole generally corresponding to a hole in the screen grid 302. Although holes are often formed by drilling, they may also be formed by other methods or combinations of methods including but not limited to milling, reaming, electro discharge machining (EDM), laser machining, water jet cutting and chemical etching. In one implementation, both the acceleration grid 304 and the screen grid 302 include the same number of holes. However, additional implementations may provide for a differing number of holes between the acceleration grid 304 and the screen grid 302. All of the holes in the acceleration grid 304 may have the same diameter or may have varying diameters across the face of the acceleration grid 304. Additionally, the distance between the holes may be the same or of varying distances. The acceleration grid 304 is illustrated in FIG. 3 as four vertical bars in a single column separated by spaces representing three drilled holes 361, 364, and 367 within the acceleration grid 304. The acceleration grid 304 is marked with minus (−) signs, representing that the acceleration grid 304 as being negatively charged or biased. A negative charge or bias on the acceleration grid 304 extracts the ions from the plasma and through the holes in the screen grid 302.

The deceleration grid 306 is positioned immediately downstream of the acceleration grid 304 in FIG. 3, separated by a distance η_{g2}. As such, the deceleration grid 306 is downstream of the discharge chamber, the screen grid 302 and the acceleration grid 304 and upstream of the work piece 314. The deceleration grid 306 comprises a plurality of holes strategically drilled through the grid, each hole generally corresponding to a hole in the acceleration grid 304. In one implementation, both the deceleration grid 306 and the acceleration grid 304 include the same number of holes. However, additional implementations may provide for a differing number of holes between the acceleration grid 304 and the deceleration grid 306. All of the holes in the deceleration grid 306 may have the same diameter or may have varying diameters across the face of the deceleration grid 306. Additionally, the distance between the holes may be the same or of varying distances. The deceleration grid 304 is illustrated in FIG. 3 as four vertical bars in a single column separated by spaces representing three drilled holes 362, 365, and 368 within the deceleration grid 306. The deceleration grid 306 is typically grounded or charged with a small negative potential or bias.

As ions pass through holes in the deceleration grid 306, the ions collide into the downstream positioned work piece 314, such as a sputter target or substrate. While the work piece 314 is shown parallel to the grids 302, 304, 306 it may also be at any arbitrary angle suitable for a particular application. In a sputtering operation, it is possible to use multiple sputter targets, wherein each target may have a different material affixed to its surface. As ions collide with the surface of a target, an amount of material from the target separates from the surface of the target, traveling in a plume toward another work piece, such as a substrate to coat the surface of a substrate (not shown). With multiple targets of differing material coats, multi-layer coatings may be created onto a single substrate.

FIG. 3 shows three ions 308, 310, and 312 passing through adjacently positioned holes in the three grids 302, 304, and 306 and colliding into the surface of the work piece 314. However, it should be understood that the three ions 308, 310, and 312 generally represent a distribution of ions flooding through the holes in the three grids 302, 304, and 306. The trajectory of the representative ion 308 is altered (e.g., in an upward direction) as the ion 308 approaches and passes through the hole 361 of the acceleration grid 304. The altered trajectory results from an offset in the hole 361 of the acceleration grid 304 relative to the adjacent hole 360 in the screen grid 302, which causes the ion 308 to travel closer to the top circumference of the acceleration grid hole 361. In this configuration, the ion 308 experiences a greater electrostatic attraction to the top circumference of the acceleration grid hole 361 as compared to the bottom circumference, which alters the trajectory of the ion 308 relative to an orthogonal center axis 350 through the acceleration grid hole 361.

In contrast, the trajectory of the ion 312 is altered in the opposite direction (e.g., downward) as the ion 312 approaches and passes through the hole 367 of the acceleration grid 304. The hole 367 of the acceleration grid 304 is also offset relative to the adjacent hole 366 of the screen grid 302. As with ion 308, the altered trajectory of ion 312 results from an intentional offset in the hole 367 of the acceleration grid 304 relative to the adjacent hole 366 in the screen grid 302, which causes the ion 312 to travel closer to the bottom circumference of the acceleration grid hole 367. In this configuration, the ion 312 experiences a greater electrostatic attraction to the bottom circumference of the acceleration grid hole 367 as compared to the top circumference, which alters the trajectory of the ion 312 relative to an orthogonal center axis 352 through the acceleration grid hole 367.

In contrast to the preceding examples of intentionally altered trajectories, the trajectory of ion 310 remains on the center axis 324 of the hole 364 of the acceleration grid 304. The trajectory of the ion 310 is unaltered because the hole 364 of the acceleration grid 304 is centered (e.g., no offset) relative to the hole 363 of the screen grid 302. In other words, the center axis (i.e., the centerline of the hole) 324 of the hole 364 of the acceleration grid 304 has the same Y-axis location as the center axis 322 of the hole 363 of the screen grid 302. The following paragraphs provide details of the alteration of an ion's trajectory as it passes through the three grids 302, 304, and 306. It is noted, that while FIG. 3 refers to offsets in the X-Axis and Y-Axis plane, the offsets may also exist in a Y-Axis and Z-Axis (not shown) plane.

As stated above, some of the holes in the acceleration grid 304 are offset relative to the adjacently positioned holes in the screen grid 302. In other words, the center axis from one of the holes in the acceleration grid 304 may be offset from the center axis from a corresponding hole of the screen grid 302. The trajectory of ion 308 illustrates an example where the hole 361 of the acceleration grid 304 is offset relative to the adjacent hole 360 of the screen grid 302. A screen grid center axis 316 of the hole 360 in the screen grid 302 has a different Y-axis location compared to an acceleration grid center axis 350 of the hole 361 of the acceleration grid 304. In this example, λ₁ represents the Y-axis distance between the screen grid center axis 316 and the acceleration grid center axis 350. Further, δ₁ represents the offset angle of the acceleration grid center axis 350 relative to the screen grid center axis 316, based on the grid separation η_{g1}.

In the illustrated implementation, location 318 illustrates the Y-axis location where the ion 308 passes through the hole 361 of the acceleration grid 304. In this example, location 318 is offset above the acceleration grid hole center axis 350 by a distance of λ₁. As the ion 308 approaches location 318, the negatively charged acceleration grid 304 electrostatically attracts the positively charged ion 308 towards the closest circumferential portion of the hole 361 of the acceleration grid. In result, the trajectory of the ion 308 is altered or steered in an upward direction as represented by the solid line extending to the work piece 314. The dashed line represents the unaltered trajectory of the ion 308 if the ion was not electrostatically steered by the intentionally configured offset between the center axes of the holes. In one implementation, as the ion 308 approaches the hole 361 of the acceleration grid 304, the electrostatic attraction begins to increase to a maximum point when the ion 308 is within the hole 361 of the acceleration grid 304. Additionally, as the ion 308 passes through the hole 361 of the acceleration grid 304 the electrostatic attraction diminishes.

Next, the ion 308 passes through the hole 362 of the deceleration grid 306. As stated above, the deceleration grid can be grounded with a neutral charge or zero electrical potential. Therefore, the deceleration grid does not substantially alter the trajectory of the ion 308, as the ion 308 passes through the hole 362 of the deceleration grid 306. In one implementation, the diameter of the hole 362 of the deceleration grid 306 is only marginally larger than the diameter of the ion beamlet exiting the acceleration grid 304. In another implementation, the hole 362 of the deceleration grid 306 is positioned such that the ion 308 passes through the center of the hole 362.

After the ion 308 passes through the hole 362 of the deceleration grid 306, the ion 308 collides into the surface of the work piece 314 at location 320. As previously stated, the dashed line represents the unaltered trajectory of the ion 308 if the ion was not electrostatically steered to alter its trajectory from the center axis 316 of the screen grid 302. A beam deflection angle, β₁, represents the angle between the centerline of a beamlet of ions with an altered trajectory and the centerline of a beamlet of ions with an unaltered trajectory. In other words, angle β₁ represents the steering angle of a beamlet relative to a non-steered beamlet.

The above example, illustrates the trajectory of a single ion 308. However, a single stream of ions, known as an ion beamlet, passes through the apertures of the group of holes 360, 361, and 362 of the three grids in a distribution across the open area of the holes. Accordingly, the position of each ion may vary slightly from the position of the ion 308. As such, the overall trajectory of successive ions may also vary slightly from the trajectory of ion 308. Further, the location where successive ions collide into the work piece 314 may also vary slightly.

The ion 310 is illustrated as passing through the apertures of the group of holes 363, 364, and 365 in the grid assembly 300. The ion 310 first passes through the hole 363 at the screen grid hole center axis 322. Next, the ion 310 passes through the hole 364 of the acceleration grid 304 at the acceleration grid hole center axis 324. In this example, the acceleration grid hole center axis 324 is aligned with the screen grid hole center axis 322. In other words, there is no substantial or intentional Y-axis differential or offset between the center axis of the holes 363, 364, and 365 of the screen grid 302 and the acceleration grid 304. Since the acceleration grid hole center axis 324 is as aligned with the screen grid hole center axis 322, there is no dominant lateral electrostatic attraction from the acceleration grid 304. Therefore, the trajectory of ion 310 remains unaltered as the ion passes through the hole 364 of the acceleration grid 304.

The ion 312 is illustrated as passing through the apertures of the group of holes 366, 367, and 368 in the grid assembly 300. In this example, the ion 312 first passes through the hole 366 of the screen grid 302. The screen grid hole center axis 328 represents the center of the hole 366 of the screen grid 302. The center axis 352 of the hole 367 of the acceleration grid 304 is offset relative to the center axis 328 of the hole 366 of the screen grid 302. As such, the acceleration grid hole center axis 352 of the hole 367 in the acceleration grid 302 has a different Y-axis location compared to the screen grid hole center axis 328 of the hole 366 of the screen grid 302. In this example, λ₂ represents the Y-axis distance between the screen grid hole center axis 328 and the acceleration grid hole center axis 352. δ₂ represents the offset angle of the acceleration grid hole center axis 352 relative to the screen grid hole center axis 328.

In the illustrated implementation, location 330 illustrates the Y-axis location where the ion 312 passes through the hole 367 of the acceleration grid 304. In this example, location 330 is offset below the acceleration grid hole center axis 352 by a distance of λ₂. As the ion 312 approaches location 330, the negatively charged acceleration grid 304 electrostatically attracts the positively charged ion 312 towards the closest circumferential portion of the hole 367 of the acceleration grid 304. In result, the trajectory of the ion 312 is altered or steered in an downward direction as represented by the solid line extending to the work piece 314. The dashed line represents the unaltered trajectory of the ion 312 if the ion was not electrostatically steered by the intentionally configured offset between the center axes of the holes. In one implementation, as the ion 312 approaches the hole 367 of the acceleration grid 304, the electrostatic attraction begins to increase to a maximum point when the ion 312 is within the hole 367 of the acceleration grid 304. Additionally, as the ion 312 passes through the hole 367 of the acceleration grid 304 the electrostatic attraction diminishes.

Next, the ion 312 passes through the hole 368 of the deceleration grid 306. As stated above, the deceleration grid can be grounded or charged with small negative potential or bias. Therefore, the deceleration grid does not substantially alter the trajectory of the ion 312, as the ion 312 passes through the hole 368 of the deceleration grid 306. In one implementation, the diameter of the hole 368 of the deceleration grid 306 is only marginally larger than the diameter of the ion beamlet. In another implementation, the hole 368 of the deceleration grid 306 is positioned such that the ion 312 passes through the center of the hole 368.

After the ion 312 passes through the hole 368 of the deceleration grid 306, the ion 312 collides into the surface of the work piece 314 at location 332. As previously stated, the dashed line represents the unaltered trajectory of the ion 312 if the ion was not electrostatically steered to alter its trajectory from the center axis 328 of the screen grid 302. A beam deflection angle, β₂, represents the angle between the centerline of a beamlet of ions with an altered trajectory and the centerline of a beamlet of ions with an unaltered trajectory. In other words, angle β₂ represents the steering angle of a beamlet relative to a non-steered beamlet.

A maximum deflection or steering angle of a beamlet exists resulting in a maximum distance the trajectory of a beamlet can be altered as the ions collide into the work piece 314. For beamlet steering using either a two or three grid assembly, the range of deflection angle is typically between 0 and 10 degrees in general practice, above which energetic ion impingement of the accelerator grid 304 by ions at the periphery of the beamlet can become a grid design or performance consideration.

In one implementation, it is possible to include one or more grids downstream of the acceleration grid 304 with appropriate hole size, relative offset and voltage settings to further increase the net steering angle of a beamlet. For example, in one implementation, a fourth grid (not shown) may be positioned between the acceleration grid 304 and the deceleration grid 306 to further alter or steer a beamlet (e.g., beyond the maximum steering angle of a three-grid assembly). In order to extend the maximum steering angle of a beamlet, the fourth grid includes a hole positioned adjacent to and yet offset from the adjacent hole from the acceleration grid 304. Further, the fourth grid may have the opposite charge polarity of ions passing through the hole. Once an ion passes through a hole in the acceleration grid 304, the ion approaches the corresponding hole in the fourth grid. The offset of the hole in the fourth grid is positioned to further attract the ion in substantially the same direction as the adjacent hole from the acceleration grid 304. Therefore, the trajectory of the ion can be further steered beyond the maximum steering angle of a three-grid assembly. In another implementation, additional grids may be used in various combinations to further increase the maximum steering angle of a four-grid assembly or to otherwise alter the trajectories of individual beamlets.

A number of factors influence the maximum deflection or steering angle of an ion beamlet as it approaches and passes through a hole of the acceleration grid 304. As previously stated, the Y-axis distance (λ) between a screen grid hole center axis and an acceleration grid hole center axis affects the steering of an ion beamlet. In other words, the greater the distance λ, the more an ion beamlet may be steered. Additionally, the distance (η_{g1}) between a screen grid and an acceleration grid affects the steering of an ion beamlet. The voltage applied to the acceleration grid also affects the steering an ion beamlet. In one implementation, the voltage applied to the screen grid may between 50 volts (V) and 10 kilovolts (kV). The voltage applied to the acceleration grid may be between −50V and −10 kV.

An electric field is present on both the upstream side and downstream side of the acceleration grid 304. For example, the electric field on the upstream side of the acceleration grid 304 is a voltage differential divided by the distance (η_{g1}) between the screen grid 302 and the acceleration grid 304. In one implementation, a formula for determining an amount of steering of an ion beamlet (e.g., beam deflection or steering angle β) is:

β=*−λ/4η_{g1})(1−(E₂/E₁))

In this formula, the unit of measurement for E₁ and E₂ is volts/mm. E₁ is calculated as [(voltage of the screen grid−voltage of the acceleration grid)/η_{g1}]. E₂ is calculated as [(voltage of the acceleration grid−voltage of the deceleration grid)/η_{g2}]. λ is a measure of the distance between the screen grid center axis and the acceleration grid center axis. η_{g1} is a measure of the lateral distance between the screen grid and the acceleration grid. η_{g2} is a measure of the lateral distance between the acceleration grid and the deceleration grid. It is noted that the above formula is but one example for calculating a beam deflection angle. Other formulae may be used to arrive at a predetermined beam deflection angle. Further, some variables may be omitted or additional variables added to a formula. In one implementation, the thickness of one or more grids may be considered in a formula for calculating a beam deflection angle.

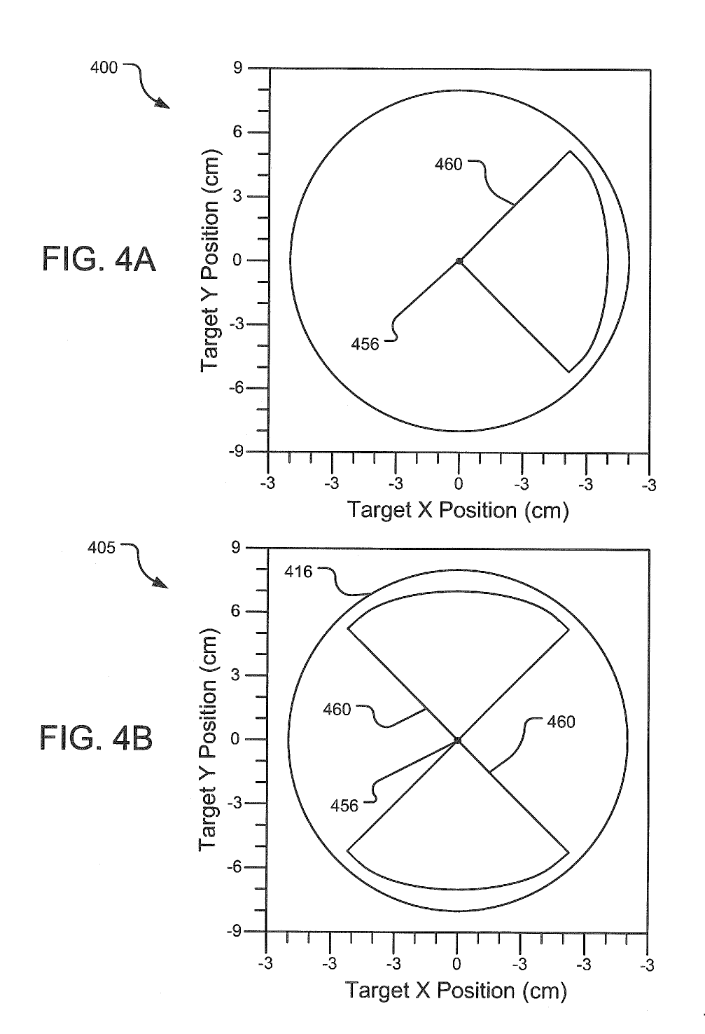

FIG. 4A illustrates an example ideal current density distribution 400 for use with a small substrate assembly (not shown). The distribution 400 is an ideal projected ion current density distribution on a destination target or work-piece 416 such as an ion beam sputter target. The ion current density distribution 400 is depicted as viewed when facing the destination target 416 (e.g., looking at the destination assembly 116 from within the ion beam 108 of FIG. 1). As discussed in further detail below, to achieve a relatively uniform wear pattern on the destination target 416, the current density within an ion beam cross-section should be relatively uniform when rotationally integrated over time at the destination target. The ideal current density distribution 400 is non-elliptical and elliptically asymmetric about a center axis 456 (i.e., not all points within the distribution 400 on concentric theoretical ellipses around axis 456 possess same value). Beamlet steering as disclosed with respect to FIG. 3, provides a way to modify the current density in the ion beam cross-section, in addition or in lieu of grid dishing. Beamlet steering (and in some implementations, grid dishing), may also provide an ion beam that achieves the relatively uniform wear pattern on the destination target.

The current density distribution 400 ideal for uniform etch of the destination targets has a pie-shaped area of current density concentration 460 in a right quadrant of the distribution 400. The pie-shape of the distribution 400 creates the relatively uniform wear pattern on the rotated destination assembly. Further, the non-elliptical distribution 400 yields a deposition plume of sputtered material matching a size and position of a substrate assembly. The non-elliptical ion beams are rotationally integrated to approximate the effect of the ion beams on rotating destination targets. Further, the non-elliptical plumes of sputtered material are rotationally integrated to approximate the effect of the plumes of sputtered material on rotating substrate assemblies. The ion beam shape influences the plume shape and distribution, however, the plume shape is not a mere reflection of the ion beam shape.

Conceptually, rotational integration may mean that as distance from the center axis 456 increases, more rotational distance on the destination target 416 is covered by the ion beam. The pie-shaped area of current density concentration 460 yields an increasing exposure to the ion current to compensate for the longer rotational distance on the destination target 416 that is covered. Thus, in effect, an uneven current density distribution 400 in a static form may be used to generate a substantially uniform current density distribution at each point of the destination target 416 when the target is rotated. Rotating the destination target 416 results in a relatively uniform wear pattern on the destination target 416. A similar rotational integration process applies to a non-elliptical plume of sputtered material impinging on a rotating substrate assembly.

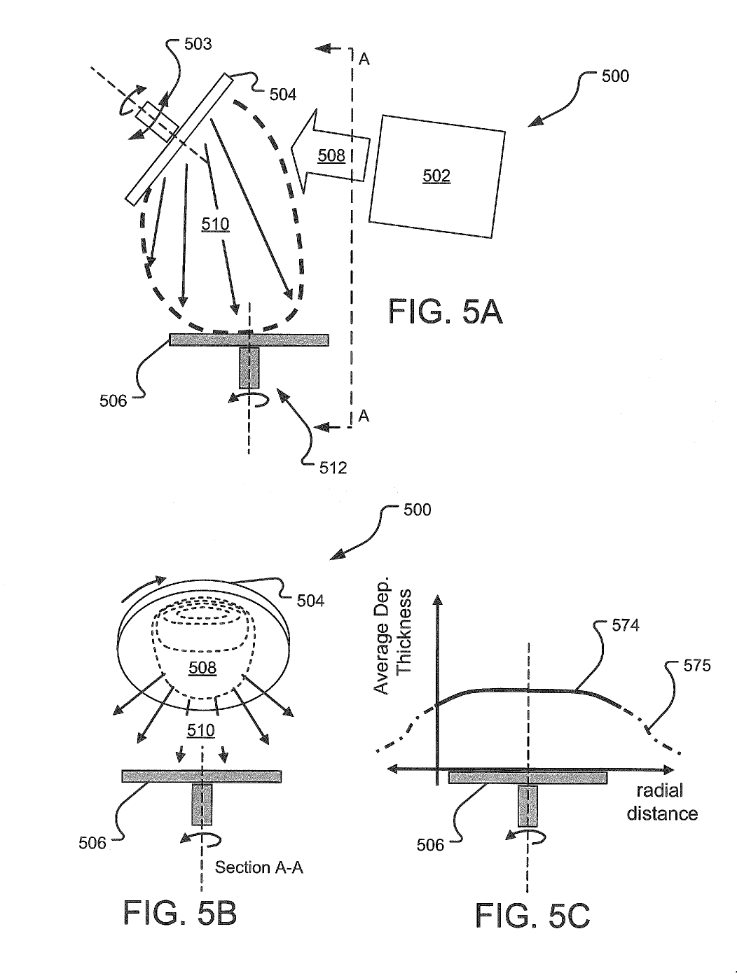

The current density concentration 460 in the right quadrant of the density distribution 400 directs the non-elliptical plume at the substrate assembly (not shown). For example, the current density concentration 460 is adapted for the small single-axis assembly 512, as depicted in FIGS. 5A to 5C. As the single-axis assembly 512 rotates, it receives a relatively uniform dose of material from the sputtered plume, with very little overspray of the non-elliptical plume outside of the single-axis assembly 512.

The ideal current density distribution 400 is adapted for relatively small substrate assemblies. The ideal current density distribution 400 results in a non-elliptical single-peak plume that is relatively focused when compared to the ideal current density distribution 405 of FIG. 4B. Further, in the implementation shown in FIG. 4A, a left quadrant of the density distribution 400 is avoided because of the greater likelihood of ions that could be deflected due to design/manufacturing error and other physical phenomena (e.g., divergence of beamlets or scattering of beam ions in collisions with ambient gas particles) and tend to miss the destination target 416 (i.e., overspray of beam ions). Such overspray of the beam ions (as distinct from the overspray of a sputter plume) may cause sputtering of other material that beam ions come in contact with, such as a vacuum chamber wall (i.e., a sputter plume of unwanted material may be generated and contaminate a substrate).

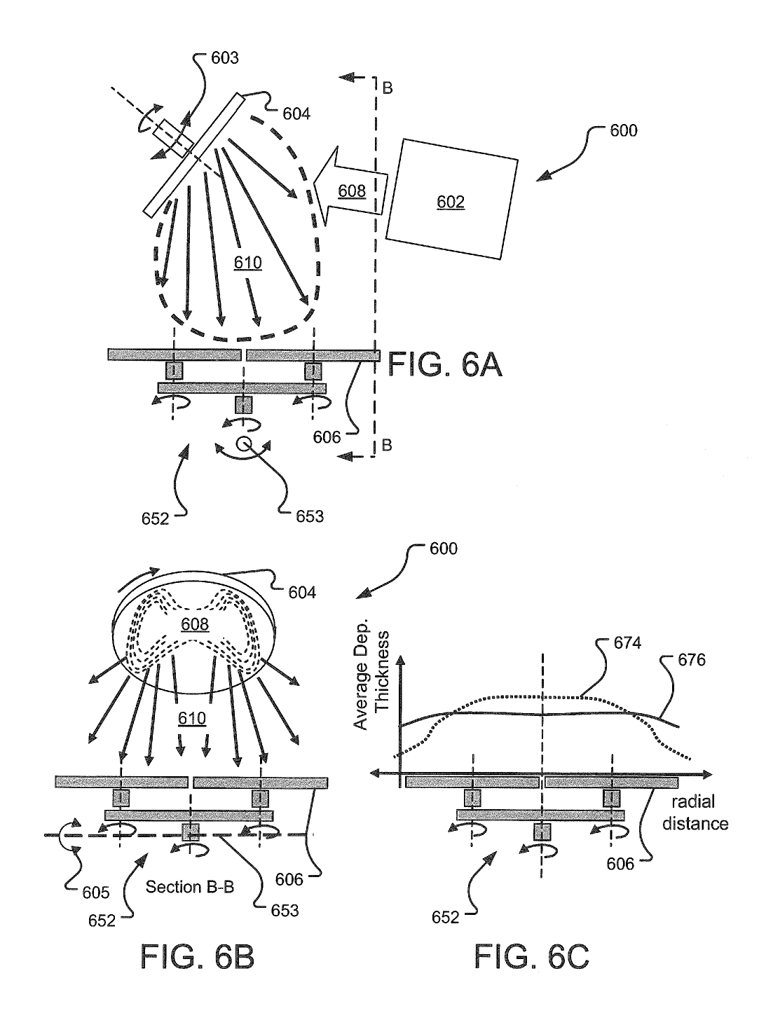

FIG. 4B illustrates an example current density distribution 405 ideal for uniform etch of the destination targets for use with a large substrate assembly (not shown). The distribution 405 is an ideal projected ion current density distribution on a destination target 416 such as an ion beam sputter target. The current density distribution 405 is depicted as viewed when facing the destination assembly 416 (e.g., looking at the destination assembly 116 from within the ion beam 108 of FIG. 1). The ideal current density distribution 405 has opposing pie-shaped areas of current density concentration 460 in top and bottom quadrants of the distribution 405 and is non-elliptical and elliptically asymmetric about a center axis 456. The pie-shapes of the distribution 405 create the relatively uniform wear pattern on the destination target 416 when the target is rotated. Further, the current density concentrations 460 in the top and bottom quadrants of the density distribution 405 expand the outward distribution of a non-elliptical plume over the large substrate assembly (not shown). For example, the large substrate assembly may be a multi-axis assembly 652 as depicted in FIGS. 6A to 6C. As the multi-axis assembly rotates, each individual rotating substrate 606 receives a relatively uniform dose of material from the non-elliptical plume, while limiting the degree of overspray of the non-elliptical plume beyond the surface of the multi-axis assembly 652.

The ideal current density distribution 405 is adapted for relatively large substrate assemblies that need a widely spread non-elliptical plume, while maintaining a relatively uniform ion beam when the ion beam is rotationally integrated. The ideal current density distribution 405 results in a non-elliptical double-peak plume when compared to the ideal current density distribution 400 of FIG. 4A. In other implementations, there are more than two pie-shaped areas of current density concentration 460 on the distribution 405 and/or the pie-shaped areas of current density concentration 460 may be larger or smaller than depicted in FIGS. 4A and 4B.

Further, in the implementation shown in FIG. 4B, a left quadrant of the density distribution 405 is avoided because of the greater likelihood of ions that could be deflected due to design/manufacturing error and other physical phenomena (e.g., divergence of beamlets or scattering of beam ions in collisions with ambient gas particles) and tend to miss the destination target (i.e., overspray of beam ions). Such overspray of the beam ions (as distinct from the overspray of a sputter plume) may cause sputtering of other material that beam ions come in contact with, such as a vacuum chamber wall (i.e., a sputter plume of unwanted material may be generated and contaminate a substrate).

FIG. 5A illustrates a first side view of an example ion beam system 500 utilizing a current density distribution for use with a single axis substrate assembly 512. As discussed above, an ion beam 508 with a non-elliptical current density distribution projects from an ion source 502 onto a rotating destination target 504. As the ion beam 508 impacts the destination target 504, a plume 510 of material is sputtered from the rotating destination target 504. In one implementation, the sputtered material is atoms of the destination target 504 dislodged by the ion beam 508. The plume 510 of material projects from the destination target 504, where the sputtered material is deposited on a substrate 506 attached to a single axis assembly 512. Though only a single substrate 506 is shown, the assembly 512 may also include a substrate holder sub-assembly holding multiple, smaller individual substrates. The target 504 may also be configured on an assembly (not shown) to tilt (as depicted by arrow 503) in either a static or oscillatory manner during the deposition process in order to further distribute wear over the target 504 and provide varying distributions of sputtered material on the single axis assembly 512.

In one implementation, the example ion beam system 500 may be equipped with one or more masks (not shown) positioned between the destination target 504 and the substrate 506. The masks may shield one or more areas of the substrate 506 from the plume 510 in order to improve deposition uniformity across substrate 506. The masks may vary widely in number, size, and orientation. The presently disclosed technology may be utilized to reduce the number and/or size of masks to generate a desired distribution uniformity of sputtered material deposition on the substrate 506.

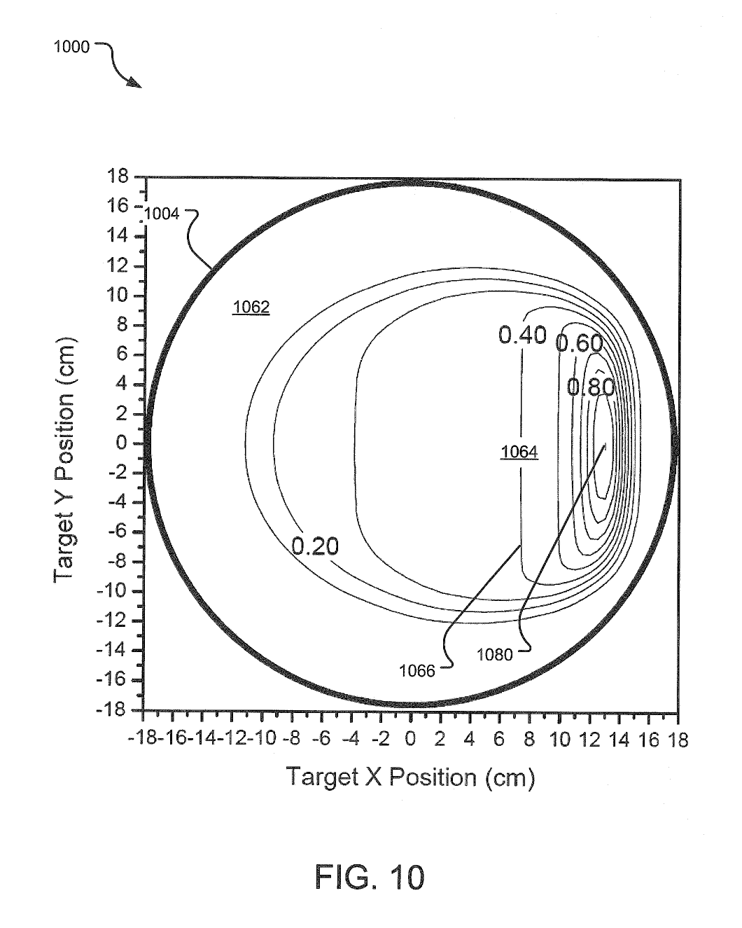

FIG. 5B illustrates a second side view of the ion beam system 500 of FIG. 5A at section A-A. The non-elliptical single-peaked ion density profile of the ion beam 508 impinging on the rotating destination target 504 is similar to that depicted in FIG. 10. The plume 510 of material sputtered from the rotating destination target 504 has a related, but not identical profile to the ion beam 508. Since each beamlet sputters material off the destination target 504 within a range of angles, the actual profile of the plume 510 may be more diffuse or generally less concentrated than the ion density profile of the ion beam 508. The plume 510 of material sputtered from the rotating destination target 504 projects from the destination target 504, where the sputtered material is deposited on a substrate 506.

FIG. 5C illustrates an example deposition flux distribution 574 on the single axis substrate assembly 512 of FIG. 5A. The deposition flux distribution 574 illustrates an example rotationally-integrated magnitude of deposition from the plume 510 of sputtered material across a plane of the substrate 506. The largest magnitude of deposition flux is generally uniformly distributed over the substrate 506, while some degree of deposition overspray 575 is directed outside of the substrate 506.

FIG. 6A illustrates a first side view of an example ion beam system 600 utilizing a current density distribution for use with a multi-axis substrate assembly 652. As discussed above, an ion beam 608 with a non-elliptical current density distribution projects from an ion source 602 onto a rotating destination target 604. As the ion beam 608 impacts the destination target 604, a plume 610 of material is sputtered from the rotating destination target 604. In one implementation, the sputtered material is atoms of the destination target 604 dislodged by the ion beam 608. The plume 610 of material sputtered from the rotating destination target 604 projects from the destination target 604 to the rotating multi-axis assembly 652, where the sputtered material is deposited on one or more substrates (e.g., substrate 606) or substrate sub-assemblies containing one or more substrates. The target 604 may also be configured on an assembly (not shown) to tilt (as depicted by arrow 603) in either a static or oscillatory manner during the deposition process in order to further distribute wear over the target 604 and provide varying distributions of sputtered material on the single axis assembly 612. The multi-axis assembly 652 may also be configured to tilt about axis 653 in either a static or an oscillatory manner during the deposition process to provide varying distributions of sputtered material on the substrate 606.

In one implementation, the example ion beam system 600 may be equipped with one or more masks (not shown) positioned between the destination target 604 and the substrate 606. The masks may shield one or more areas of the substrate 606 from the plume 610 in order to improve deposition uniformity across substrate 606. The masks may vary widely in number, size, and orientation. The presently disclosed technology may be utilized to reduce the number and/or size of masks to generate a desired distribution of sputtered material deposition on the substrate 606.

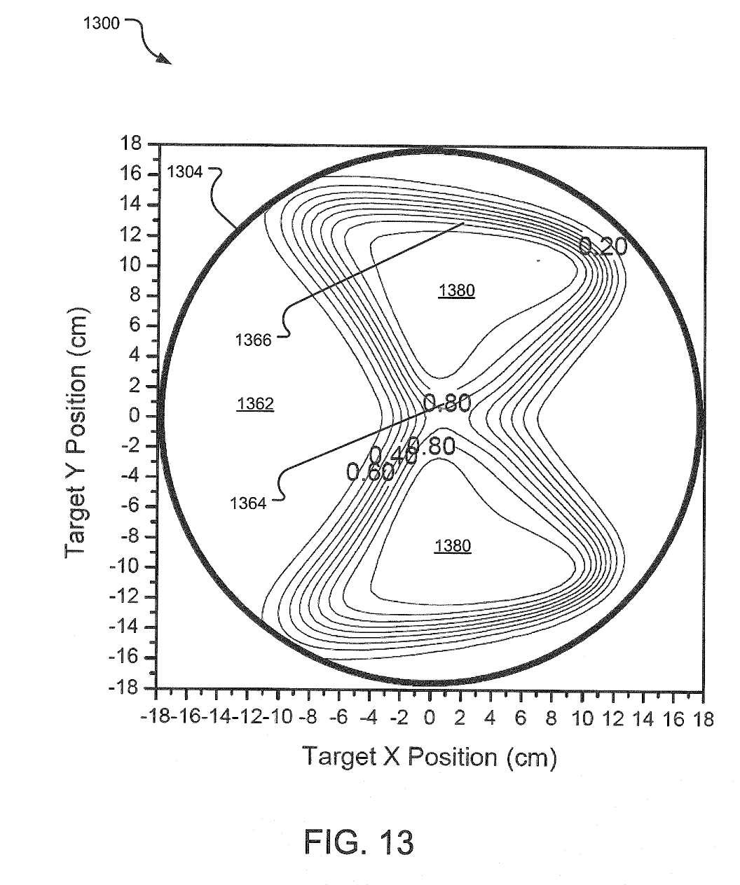

FIG. 6B illustrates a second side view of the ion beam system 600 of FIG. 6A at section B-B. The non-elliptical double-peaked ion density profile of the ion beam 608 impinging on the rotating destination target 604 is similar to that depicted in FIG. 13. The plume 610 of material sputtered from the rotating destination target 604 has a related, but not identical profile to the ion beam 608. However, since each beamlet sputters material off the destination target 604 within a range of angles, the actual profile of the plume 610 may be more diffuse or generally less concentrated than the ion density profile of the ion beam 608. The plume 610 of material sputtered from the rotating destination target 604 projects from the destination target 604 to the rotating multi-axis substrate assembly 652, where the sputtered material is deposited on one or more substrates (e.g., substrate 606). The multi-axis assembly 652 may also be configured to tilt (as depicted by arrow 605) in either a static or oscillatory manner during the deposition process to provide varying distributions of sputtered material on the substrates.

FIG. 6C illustrates an example deposition flux distribution 676 on the multi-axis substrate assembly 652 of FIG. 6A. The deposition flux distribution 676 illustrates an example rotationally-integrated magnitude of deposition from the plume 610 of sputtered material across the plane of the substrate. The largest magnitude of deposition flux is generally uniformly distributed over the multi-axis assembly 652 with relatively little overspray outside of the multi-axis assembly 652.

A deposition flux distribution 674 resulting from a non-elliptical single-peaked ion density profile (see e.g., FIG. 10) is also shown in dashed lines for comparison to the deposition flux distribution 676 resulting from a non-elliptical double-peaked ion density profile (see e.g., FIG. 13). The deposition flux distribution 674 is relatively smaller and less uniformly distributed over the multi-axis assembly 652. As a result, the deposition flux distribution 674 is more adapted for smaller assemblies (e.g., single-axis assemblies). In contrast, the deposition flux distribution 676 is relatively larger and more uniformly distributed over a larger assembly (e.g., the multi-axis assembly 652).

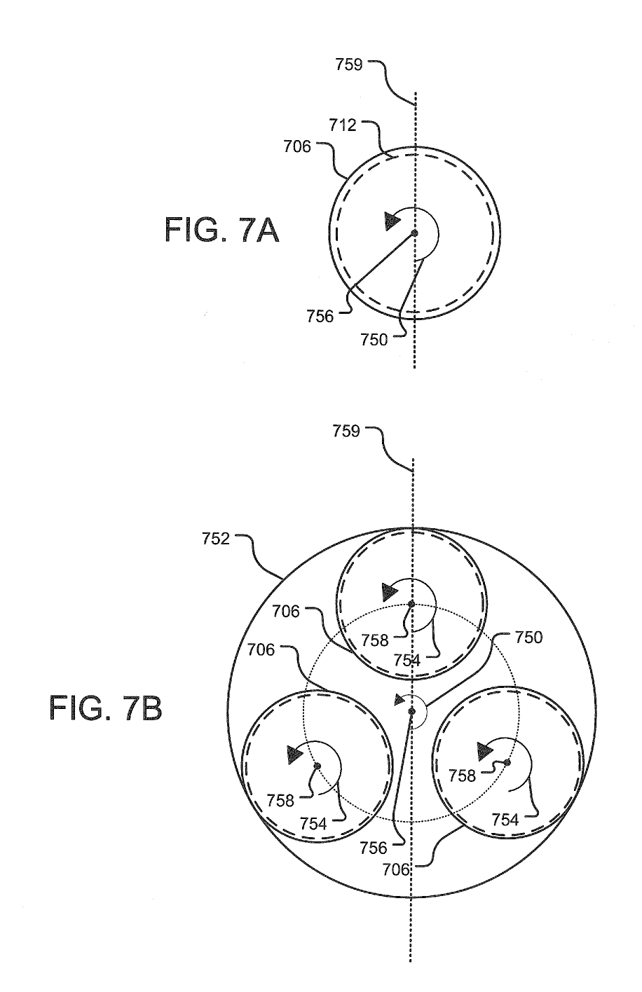

FIG. 7A illustrates an example single-axis substrate assembly 712 for use with an ion beam system incorporating the presently disclosed technology. The single-axis assembly 712 is adapted to accept a substrate 706 for sputtered material deposition using an ion source (not shown). The single-axis assembly 712, located behind the substrate 706, constrains the substrate 706 from significant translational motion in all directions. Further, the single-axis assembly 712 allows rotation of the substrate 706 only about a center axis 756, as illustrated by arrow 750. An incoming non-elliptical sputtered plume may not be uniform as it contacts the substrate 706. Rotational motion of the substrate 706 allows the non-uniform plume to more evenly coat the substrate 706, as compared to a non-rotating substrate. In one implementation, the single-axis assembly 712 is a high-speed assembly (HSF) that rotates the substrate 706 at 300 to 1200 RPM, however, the HSF may rotate at 2400 RPM or more. Further, the HSF may rotate at a lower RPM depending upon process deposition rates and needs. Still further, the single-axis assembly 712 may pivot from side-to-side about axis 759 to modify the angle of incidence of a sputtered plume (not shown) on the substrate 706. Pivoting about axis 759 may further adapt the sputtered plume to the substrate 706 size and orientation.

FIG. 7B illustrates an example multi-axis substrate assembly 752 for use with an ion beam system incorporating the presently disclosed technology. The multi-axis assembly 752, including planetary assemblies, is adapted to accept one or more substrates 706 or sub-assemblies with one or more substrates on each sub-assembly for sputtered material deposition using an ion source (not shown). The multi-axis assembly 752 constrains the substrates 706 from significant translational motion with respect to corresponding planetary axes of rotation 758 in all directions. Further, the multi-axis assembly 752 allows rotation of all the substrates 706 about a center axis 756, as illustrated by arrow 750. Each of the substrates 706 (three in the depicted implementation of FIG. 7B) are arranged on the multi-axis assembly 752 with the separate planetary axes of rotation 758, each an equal distance from the center axis 756. The substrates 706 individually rotate about their planetary axes of rotation 758, as illustrated by arrows 754, while the entire multi-axis assembly 752 rotates about center axis 756. Still further, the multi-axis assembly 752 may pivot from side-to-side about axis 759 to modify the angle of incidence of a sputtered plume (not shown) on the substrates 706. Pivoting about axis 759 may further adapt the sputtered plume to the substrates 706 size and orientation.

In both FIGS. 7A and 7B, the centerline of the sputtered plume (not shown) may or may not be coincident with the axis or rotation 756. Often some degree of offset between a peak in the sputtered plume deposition flux and the center of rotation 765 is expected in order to optimize integrated film deposition rate uniformity.

An incoming non-elliptical sputtered plume may not be uniform as it contacts the substrates 706. Rotational motion of the substrates 706 and multi-axis assembly 752 allows the non-uniform plume to more evenly coat each of the substrates 706, as compared to non-rotating substrates. The number of substrates 706 on the multi-axis assembly 752 may vary widely and may or may not share a common distance from the center axis 756. Further, the speed and direction of rotation about the center axis 756 and the planetary axes of rotation 758 may be the same or vary widely. In various implementations, the substrates 706 and multi-axis assembly 752 all rotate in the same direction, the substrates 706 rotate in an opposite direction from the multi-axis assembly 752, or the substrates 706 rotate in different directions. In one implementation, the multi-axis assembly 752 rotates at 10-20 RPM and includes 2, 3, or 4 substrates that each rotate at 100 RPM. Other numbers of substrates and rotations speeds are contemplated herein. In addition, each substrate 706 may be a substrate holder sub-assembly holding multiple, smaller individual substrates.

Still further, the size of the single-axis assembly 712 and substrate 706 of FIG. 7A and the multi-axis assembly 752 and substrates 706 of FIG. 7B may vary widely. In one implementation, the substrate 706 of FIG. 7A and substrates 706 of FIG. 7B are of a similar size (e.g., 12″ in diameter). The multi-axis assembly 752 may be 32″ in diameter. In this example implementation, a smaller, tighter deposition plume (e.g., a single-peak ion beam as shown in FIG. 10) is particularly useful for the smaller overall size of the single-axis assembly 712. Conversely, a larger deposition plume (e.g., a double-peak ion beam as shown in FIG. 13) is particularly useful for the larger overall size of the multi-axis assembly 752.

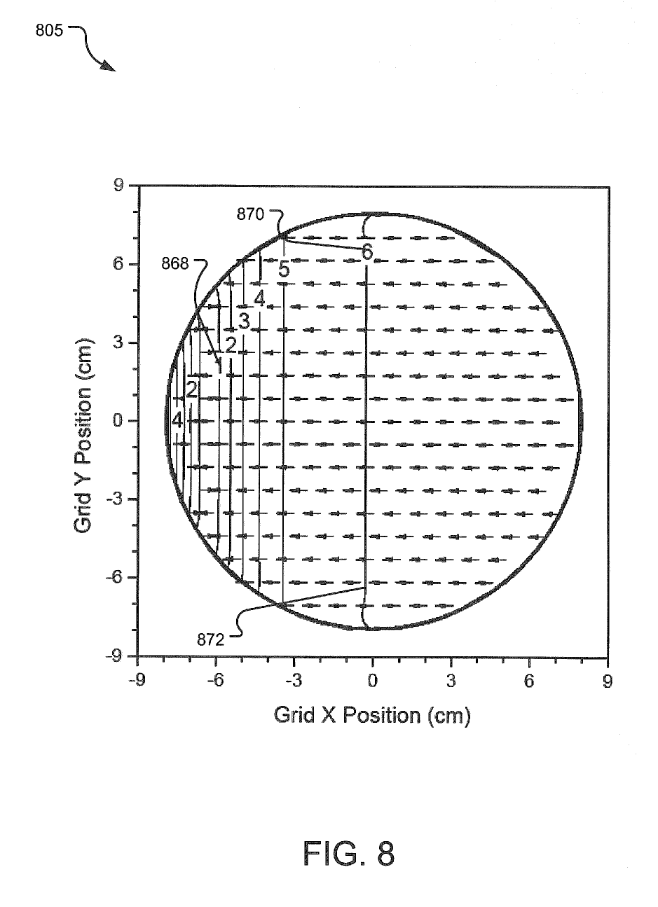

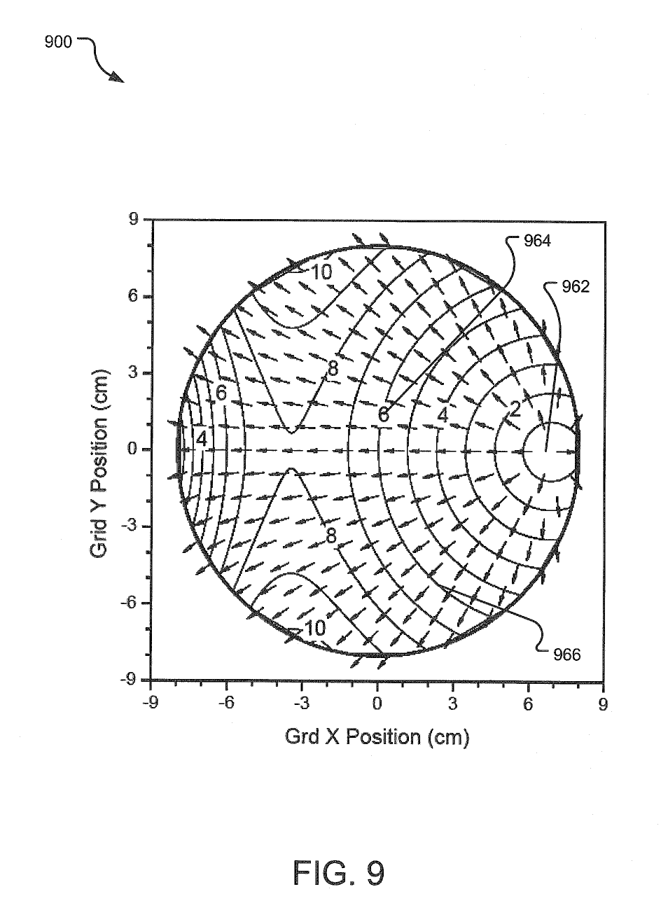

FIG. 8 illustrates an example beamlet steering diagram 800 using hole offsets for steering a single-peak ion beam. While the effect of ion beam grid dishing (discussed with respect to FIG. 9) may provide for expanding the size of the ion beam in a elliptically symmetric manner, in order to achieve an ion beam that approximates a desired current density distribution (e.g., the ideal current density distribution 400 of FIG. 4A), beamlets within the ion beam may be steered in a non-elliptical manner as well. The beamlet steering diagram 800 illustrates beamlets generally being steered toward the left side of the ion beam exiting the beam grid when facing the grid surface (e.g., looking at the ion source 102 from within the ion beam 108 of FIG. 1).

More specifically, the beamlet steering diagram 800 illustrates an ion beam cross-section with arrows indicating beamlet steering direction at X-Y locations on the grid surface and lines with numerals (i.e., 1, 2, 3, 4, 5, and 6) indicating beamlet steering magnitude in degrees at X-Y locations on the grid surface. For example, at an X-Y location 868, the magnitude of steering is one degree, whereas at an X-Y location 870, the magnitude of steering is six degrees. Note that an entire line 872 passing through the location 870 denotes locations where the magnitude of steering is equal to six degrees. Note also that the arrows reverse direction near location 868, wherein the magnitude of steering is one degree. Thus, beamlet steering diagram 800, in effect, provides a contour plot of the magnitude of beamlet steering at various X-Y locations on the grid surface, together with the direction of such steering as depicted by the arrows using hole offsets alone.

FIG. 9 illustrates an example beamlet steering diagram 900 using grid dishing and hole offsets for steering a single-peak ion beam. The diagram 900 is a combination of the beamlet steering provided by dishing and the beamlet steering provided by hole offsets as depicted in FIG. 8. The beamlet steering diagram 900 is intended to yield an ion beam current density profile (see FIG. 10) that approximates the ideal current density profile 400 depicted in FIG. 4A. The beamlet steering diagram 900 illustrates beamlets generally being steered toward the left side of the ion beam exiting the beam grid when facing the grid surface (e.g., looking at the ion source 102 from within the ion beam 108 of FIG. 1).

In many implementations, an ion source is significantly smaller than a corresponding destination assembly and substrate assembly in an ion beam system. As a result, dishing may be used to steer an ion beam exiting the ion source divergently such that it becomes bigger with distance from the ion source. A cross-sectional size of the ion beam may then match a size of the destination assembly and a cross-sectional size of a plume sputtered from the destination assembly may then match the size of the substrate assembly. Uniform dishing is desired for manufacturability and maintenance of dishing shape. It is also desirable for predictability of the 3D form of the grid when the grid is in use and heated up. However, asymmetric dishing is contemplated (in addition or in lieu of hole offsets) to intentionally effect asymmetric ion beamlet steering as disclosed herein.

When ion beam grids in an ion source are convexly dished (when viewed from the exit of the ion beam grids), steering angles of beamlets exiting the beam grids are directed outwardly, away from a longitudinal center of the ion beam. As a result, the ion beam exiting the ion beam grids is divergent and becomes larger with distance from the ion source. In another implementation, the ion beam grids in an ion source are concavely dished (when viewing the exit of the ion beam grids) in order to direct the steering angles of beamlets exiting the beam grids inwardly. As a result, the ion beam exiting the ion beam grids is convergent and becomes smaller with distance from the ion source toward a focal point of the dishing shape.

The beamlet steering diagram 900 illustrates an ion beam cross-section with arrows indicating beamlet steering direction at X-Y locations on the grid surface and lines with numerals (i.e., 2, 4, 6, 8, & 10) indicating beamlet steering magnitude in degrees at X-Y locations on the grid surface. For example, at an X-Y location 962, the magnitude of steering is near zero, whereas at an X-Y location 964, the magnitude of steering is six degrees. Note that an entire arc 966 passing through the location 964 denotes locations where the magnitude of steering is equal to six degrees. Thus, beamlet steering diagram 900, in effect, provides a contour plot of the magnitude of beamlet steering at various X-Y locations on the grid surface, together with the direction of such steering as depicted by the arrows using both grid dishing and hole offsets.

FIG. 10 illustrates an example single-peak ion current density profile 1000 resulting from the beamlet steering depicted in FIG. 9 impinging on a destination assembly 1004. In the depicted implementation, the ion beam impinges on the destination assembly 1004 at a 45 degree tilt with respect to an ion source centerline and the ion current density upstream of the grid is uniform across the entire area of ion source. The ion current density profile 1000 is non-elliptical and concentrated with a single-peak 1080 (e.g., an area of maximum ion current density) at the right side and near the vertical middle of the destination assembly 1004 when facing the destination assembly 1004 (e.g., looking at the destination assembly 116 from within the ion beam 108 of FIG. 1). This corresponds to the beamlets generally being steered toward the left side of the ion beam exiting the beam grid when facing the grid surface (e.g., looking at the ion source 102 from within the ion beam 108 of FIG. 1).

More specifically, the ion current density profile 1000 illustrates an ion beam cross-section having contour lines with numerals (i.e., 0.2, 0.4, 0.6, & 0.8 of peak current density) indicating the relative (or normalized) current density at X-Y locations on the destination assembly. For example, at an X-Y location 1062, the ion current density is approximately zero, whereas at an X-Y location 1064, the ion current density is approximately 40% of peak current density. Note that an entire contour 1066 passing through the location 1064 denotes locations where the ion current density is approximately 40% of peak current density.

As discussed with regard to FIG. 4A, the non-elliptical ion current density profile 1000 is adapted to provide a distributed wear pattern on the destination assembly 1004 as the destination assembly 1004 rotates. As a result, the ion current density profile 1000 yields a substantially uniform profile on the destination assembly when rotationally integrated. Further, the ion current density profile 1000 is also adapted to provide a non-elliptical single-peak plume sputtered from the destination assembly that impinges a small substrate assembly as discussed with regard to FIG. 4A. One or both of dishing configurations and hole offsets are means to achieve the circular asymmetric steering of ion beamlets, non-elliptical ion beams, and/or non-elliptical sputtered plume disclosed herein.

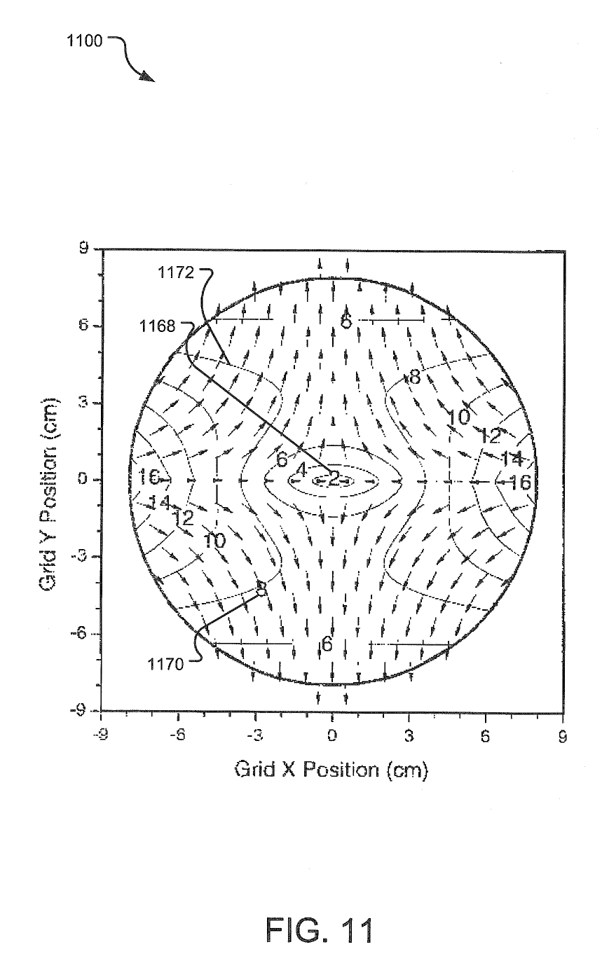

FIG. 11 illustrates an example total beamlet steering diagram 1100 using hole offsets for steering a double-peak ion beam. While the effect of ion beam grid dishing (discussed with respect to FIG. 9) may provide for expanding the size of the ion beam in a elliptically symmetric manner, in order to achieve a double-peak ion beam that approximates a desired current density distribution (e.g., the ideal current density distribution 405 of FIG. 4B), beamlets within the ion beam may be steered in a non-elliptical manner as well. The beamlet steering diagram 1100 illustrates beamlets generally being steered toward a top-center and a bottom-center of the ion beam exiting the beam grid when facing the grid surface (e.g., looking at the ion source 102 from within the ion beam 108 of FIG. 1).

More specifically, the beamlet steering diagram 1100 illustrates an ion beam cross-section with arrows indicating beamlet steering direction at X-Y locations on the grid surface and lines with numerals (i.e., 2, 4, 6, 8, 10, 12, 14, and 16) indicating beamlet steering magnitude in degrees at X-Y locations on the grid surface. For example, at an X-Y location 1168, the magnitude of steering is two degrees, whereas at an X-Y location 1170, the magnitude of steering is eight degrees. Note that an entire line 1172 passing through the location 1170 denotes locations where the magnitude of steering is equal to eight degrees. Thus, beamlet steering diagram 1100, in effect, provides a contour plot of the magnitude of beamlet steering at various X-Y locations on the grid surface, together with the direction of such steering as depicted by the arrows using hole offsets alone.

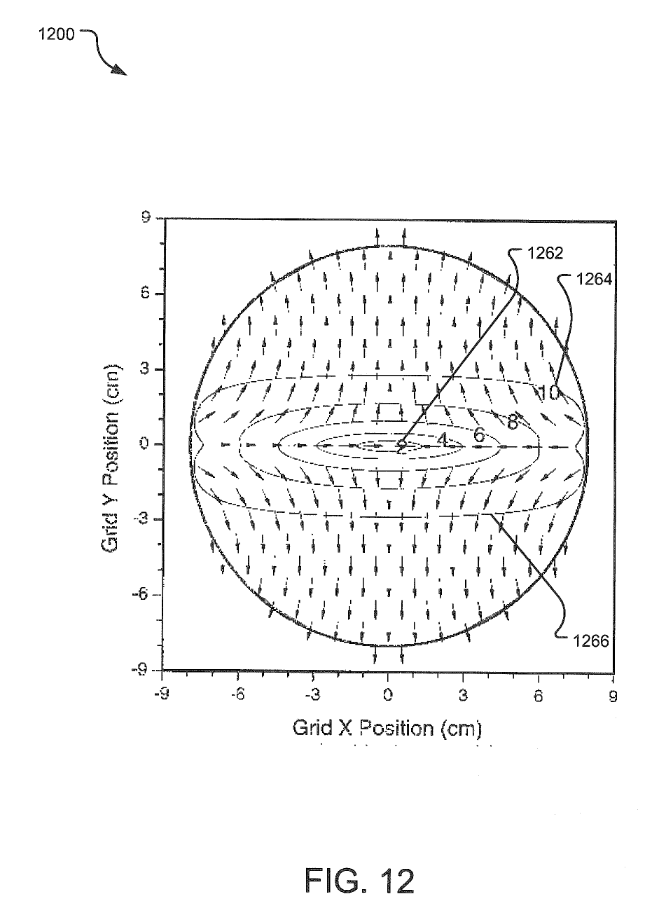

FIG. 12 illustrates an example beamlet steering diagram 1200 using grid dishing and hole offsets for steering a double-peak ion beam. The diagram 1200 is a combination of the beamlet steering provided by dishing and the beamlet steering provided by hole offsets as depicted in FIG. 11. The beamlet steering diagram 1200 is intended to yield an ion beam current density profile (see FIG. 13) that approximates the ideal current density profile 405 depicted in FIG. 4B. The beamlet steering diagram 1200 illustrates beamlets generally being steered toward a top-center and a bottom-center of the ion beam exiting the beam grid when facing the grid surface (e.g., looking at the ion source 102 from within the ion beam 108 of FIG. 1).

More specifically, the beamlet steering diagram 1200 illustrates an ion beam cross-section with arrows indicating beamlet steering direction at X-Y locations on the grid surface and lines with numerals (i.e., 2, 4, 6, 8, & 10) indicating beamlet steering magnitude in degrees at X-Y locations on the grid surface. For example, at an X-Y location 1262, the magnitude of steering is two degrees, whereas at an X-Y location 1264, the magnitude of steering is ten degrees. Note that an entire arc 1266 passing through the location 1264 denotes locations where the magnitude of steering is equal to ten degrees. Thus, beamlet steering diagram 1200, in effect, provides a contour plot of the magnitude of beamlet steering at various X-Y locations on the grid surface, together with the direction of such steering as depicted by the arrows using both grid dishing and hole offsets.

FIG. 13 illustrates an example ion current density profile 1300 resulting from the beamlet steering depicted in FIG. 12 impinging on a destination assembly 1304. In the depicted implementation, the ion beam impinges on the destination assembly 1304 at a 45 degree tilt with respect to an ion source centerline and the ion current density upstream of the grid is uniform across the entire area of ion source. The ion current density profile 1300 is non-elliptical and concentrated with peaks 1380 (e.g., local areas of maximum ion current density) at the top-center and a bottom-center of the destination assembly 1304 when facing the destination assembly 1304 (e.g., looking at the destination assembly 116 from within the ion beam 108 of FIG. 1). This corresponds to the beamlets generally being steered toward the top-center and a bottom-center of the ion beam exiting the beam grid when facing the grid surface (e.g., looking at the ion source 102 from within the ion beam 108 of FIG. 1).

More specifically, the ion current density profile 1300 illustrates an ion beam cross-section having contour lines with numerals (i.e., 0.2, 0.4, 0.6, & 0.8 of peak current density) indicating the relative (or normalized) current density at X-Y locations on the destination assembly. For example, at an X-Y location 1362, the ion current density is approximately zero, whereas at an X-Y location 1364, the ion current density is approximately 80% of peak current density. Note that an entire contour 1366 passing through the location 1364 denotes locations where the ion current density is approximately 80% of peak current density.

As discussed with regard to FIG. 4B, the non-elliptical ion current density profile 1300 is adapted to provide a distributed wear pattern on the destination assembly 1304 as the destination assembly 1304 rotates. As a result, the ion current density profile 1300 yields a substantially uniform profile on the destination assembly when rotationally integrated. Further, the ion current density profile 1300 is also adapted to provide a non-elliptical double-peak plume sputtered from the destination assembly that impinges a large substrate assembly as discussed with regard to FIG. 4B. One or both of dishing configurations and hole offsets may achieve the circular asymmetric steering of ion beamlets, non-elliptical ion beams, and/or non-elliptical sputtered plumes disclosed herein.

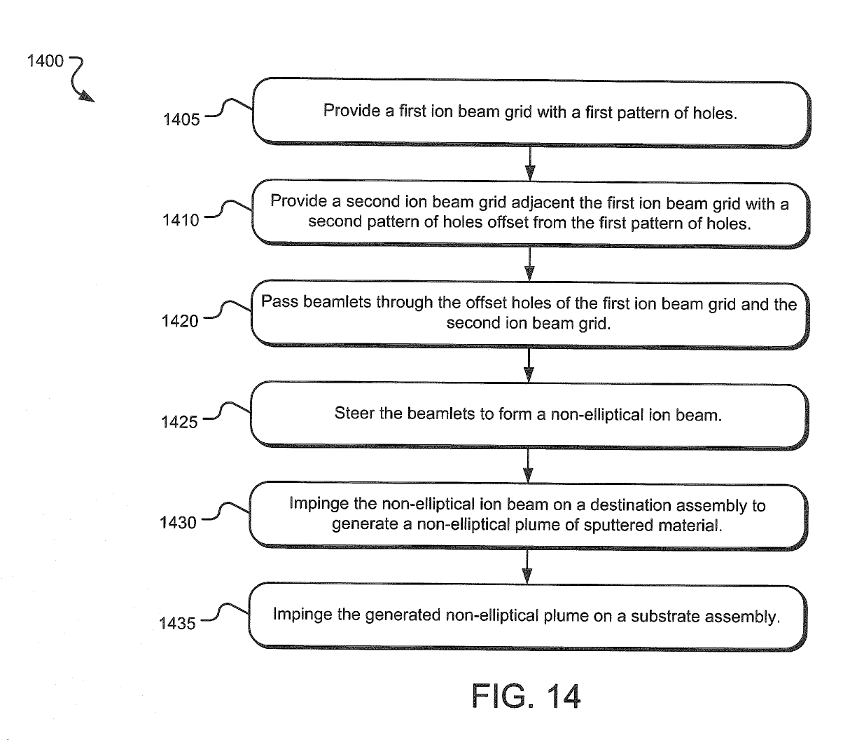

FIG. 14 illustrates example operations 1400 for creating a non-elliptical plume adapted to impinge on a substrate assembly. In a first providing operation 1405, a first ion beam grid with a first pattern of holes is provided. In a second providing operation 1410, a second ion beam grid with a second pattern of holes offset from the first pattern of holes is provided. The quantity and direction of offset determines the quantity and direction of steering individual beamlets passing through corresponding holes in the first ion beam grid and the second ion beam grid. The beamlet steering as a whole creates a varied current density distribution within a cross-section of an ion beam. Further, one or both the ion beam grids may be dished. The dishing provides additional beamlet steering, primarily making the resulting ion beam divergent or convergent depending on whether the dishing is convex or concave, respectively. In another implementation, all the beamlet steering is caused by dishing of one or both of the ion beam grids.

In a passing operation 1420, beamlets are passed through the offset holes in the first ion beam grid and the second ion beam grid and directed toward a destination assembly. In a steering operation 1425, the beamlets are steered to form a non-elliptical ion beam. The cross-sectional current density profile of the non-elliptical ion beam is chosen to result in relatively even wear on a rotating destination assembly from which material is sputtered. Further, the cross-sectional current density profile of the non-elliptical ion beam is chosen to result in a substantially uniform deposition of sputtered material from the rotating destination assembly with reduced overspray on a rotating substrate assembly.

In a first impinging operation 1430, the non-elliptical ion beam is impinged on the destination assembly. When the ion beam impacts the destination assembly, material is sputtered from the destination assembly into a non-elliptical ion beam plume of sputtered material. The generated non-elliptical ion beam plume of sputtered material is directed toward the rotating substrate assembly. In a second impinging operation 1435, the non-elliptical plume is impinged on the substrate assembly. The substrate assembly may have a single substrate rotating about a center axis (i.e., a single-axis substrate assembly) or one or more substrates, each individually rotating and the whole assembly rotating as well (i.e., a multi-axis substrate assembly). In addition, there may be multiple substrate sub-assemblies on the substrate assembly holding multiple substrates on each substrate sub-assembly. The assemblies and corresponding substrate(s) may have a variety of sizes and configurations. The cross-sectional current density profile of the non-elliptical ion beam is chosen to provide a substantially uniform deposition of sputtered material from the rotating destination assembly with reduced overspray on a particular rotating substrate assembly.

A set of offsets between corresponding holes in two or more ion beam grids is one possible structure for steering ion beamlets to form an ion beam that impinges a non-elliptical predetermined area on a destination target. Further, dishing of one or more of the ion beam grids is another possible structure for steering the ion beamlets to form the ion beam that impinges the non-elliptical predetermined area on the destination target. Still further, a combination of offsets and dishing is yet another possible structure for steering the ion beamlets to form the ion beam that impinges the non-elliptical predetermined area on the destination target.

The logical operations may be performed in any order, unless explicitly claimed otherwise or a specific order is inherently necessitated by the claim language. The above specification, examples, and data provide a complete description of the structure and use of exemplary embodiments of the invention. Since many embodiments of the invention can be made without departing from the spirit and scope of the invention, the invention resides in the claims hereinafter appended. Furthermore, structural features of the different embodiments may be combined in yet another embodiment without departing from the recited claims.

What is claimed is:

1. A system comprising:
a grid having a substantially elliptical pattern of holes for passing beamlets of ions there through, the beamlets exiting the grid are steered to form an ion beam that impinges a non-elliptical predetermined area on a destination work-piece.

2. The system of claim 1, wherein the ion beam sputters a plume of material from the destination work-piece, the plume being dependant upon the non-elliptical shape of the predetermined area.

3. The system of claim 2, wherein the plume deposits the material on a substrate assembly with one or more substrates mounted thereon.

4. The system of claim 3, wherein the material is deposited substantially uniformly when the substrate assembly is rotated.

5. The system of claim 1, wherein the beamlets exiting the grid are further steered to form an elliptically asymmetric ion current density profile of the ion beam at the predetermined area.

6. The system of claim 1, wherein the grid is placed adjacent to another grid and offsets between pairs of adjacent holes on the grids cause the beamlet steering.

7. The system of claim 1, wherein dishing of the grid causes the beamlet steering.

8. The system of claim 2, wherein the plume includes a concentrated sputtered material density emanating from the non-elliptical predetermined area, the non-elliptical predetermined area having an area of maximum sputtering offset from a center of the destination work-piece.

9. The system of claim 2, wherein the plume includes a concentrated sputtered material density emanating from the non-elliptical predetermined area, the non-elliptical predetermined area having two opposing areas of local maximum sputtering, each area offset from a center of the destination work-piece.

10. The system of claim 9, wherein the plume deposits material in an elongated pattern on a plane occupied by a rotating substrate assembly with one or more rotating substrates mounted thereon.

11. The system of claim 1, wherein the substantially elliptical pattern of holes is substantially circular.

12. A method of sputtering material from a destination work-piece comprising:
steering individual ion beamlets from a first substantially elliptical pattern of holes in a first grid to form an ion beam that impinges a non-elliptical predetermined area on the destination work-piece.

13. The method of claim 12, wherein the ion beam sputters a plume of material from the destination work-piece, the plume being dependant upon the non-elliptical shape of the predetermined area.

14. The method of claim 13, wherein the plume deposits the material on a substrate assembly with one or more substrates mounted thereon.

15. The method of claim 14, wherein the material is deposited substantially uniformly when the substrate assembly is rotated.

16. The method of claim 12, wherein the beamlets exiting the first grid are further steered to form an elliptically asymmetric ion current density profile of the ion beam at the predetermined area.

17. The method of claim 12, further comprising:
arranging the first grid with the first substantially elliptical pattern of holes adjacent a second grid with a second substantially elliptical pattern of holes;
passing the individual beamlets of ions through pairs of adjacent holes in the first grid and the second grid, wherein an offset between each pair of adjacent holes steers the beamlets to form the ion beam.

18. The method of claim 17, wherein dishing of one or both of the first and second grids further steers the individual ion beamlets.

19. The method of claim 13, wherein the plume includes a concentrated sputtered material density emanating from the non-elliptical predetermined area, the non-elliptical predetermined area having an area of maximum sputtering offset from a center of the destination work-piece.

20. The method of claim 13, wherein the plume includes a concentrated sputtered material density emanating from the non-elliptical predetermined area, the non-elliptical predetermined area having two opposing areas of local maximum sputtering, each area offset from a center of the destination work-piece.

21. The method of claim 20, wherein the plume deposits material in an elongated pattern on a plane occupied by a rotating substrate assembly with one or more rotating substrates mounted thereon.

22. A substrate configured to receive a substantially uniform deposition of sputtered material using the method of claim 12.

23. The method of claim 12, wherein the substantially elliptical pattern of holes is substantially circular.

24. An ion beam system comprising:
a destination target;
an ion source including one or more grids, each with a substantially elliptical pattern of holes emanating beamlets of ions to form an ion beam, wherein the ion beam impinges a non-elliptical predetermined area on the destination target and generates a plume of material sputtered from the destination target; and
a substrate assembly, wherein the plume of material includes a concentrated sputtered material density emanating from the non-elliptical predetermined area and impinging on the substrate assembly, the non-elliptical predetermined area having one or more areas of local maximum sputtering offset from a center of the destination target.

25. The ion beam system of claim 24, wherein the plume of material is deposited substantially uniformly on the substrate assembly, when the substrate assembly is rotated.

26. The ion beam system of claim 24, wherein the beamlets exiting the ion source are further steered to form an elliptically asymmetric ion current density profile of the ion beam at the predetermined area.

27. A system comprising:
a pair of ion beam grids, each with a substantially elliptical pattern of holes; and
means for steering individual ion beamlets formed in the ion beam grids configured to output an ion beam that impinges a non-elliptical predetermined area on a destination work-piece.
